(19) United States
(12) Patent Application Publication
(10) Pub. No.: US 2008/0296742 A1
(43) Pub. Date: Dec. 4, 2008

(54) SEMICONDUCTOR DEVICE, AND METHOD FOR FABRICATING THEREOF

(76) Inventor: Dae-Young Kim, Suwon-si (KR)

Correspondence Address: SHERR & VAUGHN, PLLC, 620 HERNDON PARKWAY, SUITE 200, HERNDON, VA, 20170, US

(21) Appl. No.: 12/131,072

(22) Filed: May 31, 2008

(30) Foreign Application Priority Data
Jun. 1, 2007 (KR) 10-2007-0053764

(51) Int. Cl. H01L 29/423; H01L 21/28

(52) U.S. Cl. 257/637; 438/591; 257/E29.132; 257/E21.192

(57) ABSTRACT

A semiconductor device having silicon-oxide-nitride-oxide-silicon (SONOS) structure that overcomes spatial limitations which trap charges by not utilizing a flat, planar structure of the ONO film including a charging trap layer, thereby making it possible to improve reliability for data preserving characteristic of a SONOS device.

The present application claims priority under 35 U.S.C. 119 to Korean Patent Application No. P 10-2007-0053764 (filed on Jun. 1, 2007), which is hereby incorporated by reference in its entirety.

### BACKGROUND

A semiconductor memory may be generally divided into a volatile memory and a non-volatile memory. Most volatile memories are RAMs, such as a dynamic RAM (DRAM), a static RAM (SRAM), etc. and have a feature that can preserve inputs of data when a power supply is applied or cannot preserve data due to the volatilization of data when a power supply is removed. Most of the non-volatile memories are a read only memory (ROM) and have a feature that can preserve data even when a power supply is removed. Non-volatile memory, in view of current process technology, may be generally divided into a floating gate system and a metal insulator semiconductor system whereby two kinds of dielectric layers are stacked double or triple.

A representative memory of the floating gate system that implements memory characteristics using a potential well may include an EPROM tunnel oxide (ETOX) structure widely used as an electrically erasable programmable ROM (EEPROM). On the other hand, the MIS system performs a memory function using a dielectric layer bulk, a dielectric-dielectric interface, and a trap existing in a dielectric-semiconductor interface. A representative example may include a metal/silicon ONO semiconductor (MONOS/SONOS) structure mainly used as a flash EEPROM

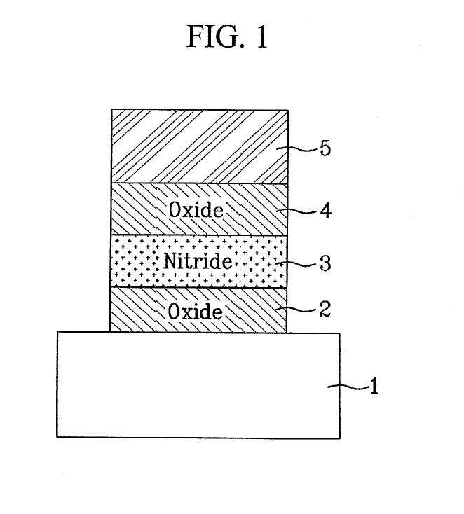

Example FIG. 1 illustrates a vertical cross-sectional view of a semiconductor device having a SONOS structure that may include a cell in the SONOS structure formed of ONO films 2, 3 and 4 configured of dielectric layers sequentially stacked on and/or over an uppermost surface of an active region of semiconductor substrate 1, and gate electrode 5 formed on and/or over the uppermost surface of ONO films 2, 3 and 4. ONO films 2, 3 and 4 may be formed by sequentially stacking tunnel oxide layer 2, a nitride layer serving as charging trap layer 3 and charge barrier layer 4 on and/or over the uppermost surface of the active region of semiconductor substrate 1. Gate electrode 5 may be formed of conductive polysilicon. A source/drain junction may be formed in semiconductor substrate 1. ONO films 2, 3 and 4 may perform a role of storing charges in the SONOS structure.

If a positive (+) voltage is applied to gate electrode 5, electrons may be induced onto a silicon surface. If a higher voltage is applied to gate electrode 5, some of the induced electrons obtain sufficient energy to FN-tunnel tunnel dielectric layer 2. The tunneled electrons may be trapped in charging trap layer 3 to have negative charges. If a high voltage is applied to gate electrode 5 for a predetermined time, the threshold voltage Vₜₕ of the transistor may rise by negative charges trapped in charging trap layer 3 to turn off the transistor. Thereby, a program operation is completed. The program characteristic means the trap of charges according to an application of voltage for the program operation to gate electrode 5.

The program characteristic in the cell of the SONOS structure is one of very important development problems. The program characteristic is closely related to the thickness of the ONO film and the density of the trap site existing in the ONO film, etc. In order to improve the program characteristic, a method of increasing an amount of electrons FN-tunneled by making the thickness of the ONO film considerably thin has been attempted. Also, a method of improving the program characteristic by changing layer quality in the nitride layer has been attempted. However, in the SONOS structure, the thickness of the ONO film is somewhat determined by the intensity of given electric field. Therefore, if the thickness of the ONO film is too thin in order to improve the program characteristic, the dielectric layer is destroyed by a high electric field, and thus, data preserving characteristic and endurance characteristics can be vulnerable. Furthermore, current technology has a limitation of formation of a sufficiently thin ONO film. Also, although the sufficiently thin ONO film is formed, some of charges trapped in the thin ONO film are lost or deteriorated due to thermal influence from the outside or repeated write and erase operations. In other words, many cases where the charges trapped in the nitride layer are lost in the process of performing the programming and the erase occur so that the reliability of the SONOS device for the data preserving characteristic is vulnerable.

### SUMMARY

Embodiments relate to a semiconductor device, and more particularly to a semiconductor device such as silicon-oxide-nitride-oxide-silicon (SONOS) device and a method for fabricating thereof.

Embodiments relate to a semiconductor device and a method for fabricating thereof capable of improving reliability for data preserving characteristic of a SONOS device.

Embodiments relate to a semiconductor device and a method for fabricating thereof that can overcome a spatial limit trapping charges by escaping a flat or planar structure of an ONO film including a charging trap layer.

Embodiments relate to a semiconductor device and a method for fabricating thereof that can effectively increase an amount of charges tunneled using a recess gate structure to improve data preserving characteristic of a SONOS device.

Embodiments relate to a semiconductor device that can include at least one of the following: a wafer having a trench in an active region; and a first oxide film, a nitride film, and a second oxide film sequentially formed on and/or over the trench to have a rugged structure by the trench. Preferably, the trench is formed on the wafer at a depth of about 100 Å by performing a dry etching on the wafer. Preferably, the first oxide film is formed on and/or over the trench at a thickness of 20 Å by a wet etching, the nitride film is formed on and/or over the uppermost surface of the first oxide film at a thickness of 60 Å, and the second oxide film is formed on and/or over the uppermost surface of the nitride film at a thickness of 3000 Å by hot temperature oxide. Herein, the second oxide film is planarized with a chemical mechanical polishing (CMP) and a gate formed on and/or over the planarized uppermost surface thereof at a thickness of 2100 Å.

Embodiments relate to a method for fabricating a semiconductor device that can include at least one of the following steps: forming a trench on and/or over a wafer; and then sequentially forming a first oxide film and a nitride film rugged along an inner wall of the trench on and/or over the wafer including the trench; and then forming a second oxide film on and/or over the nitride film and planarizing the second oxide film; and then forming a polysilicon layer by depositing polysilicon for forming a gate on and/or over the planarized second oxide film; and then forming a recessed gate by patterning the polysilicon layer. Preferably, the step of forming the trench on and/or over the wafer includes the steps of: forming a photo resist pattern for the trench on and/or over the wafer; and then etching the silicon layer to a predetermined depth using the formed photo resist pattern as an etch mask; and then removing the photo resist pattern from the wafer. Herein, the photo resist is formed on and/or over the wafer at a thickness of 1000 Å A to form the photo resist pattern. Also, the silicon layer of the wafer is removed by about 100 Å by the dry etching to form the trench. Preferably, the first oxide film is formed at a thickness of 20 Å by the wet oxidation, the nitride film is formed at a thickness of 60 Å and the second oxide film is deposited at a thickness of 3000 Å by high temperature oxidation and then planarized with a chemical mechanical polishing. Preferably, the polysilicon is deposited at a thickness of 2100 Å. Preferably, the polysilicon layer is patterned to form the recessed gate on the upper of the trench.

Embodiments relate to a semiconductor device that can include at least one of the following: a wafer having a trench formed in an active region thereof; a first oxide film, a nitride film, and a second oxide film sequentially formed on the trench. In accordance with embodiments, the nitride film includes a lateral portion extending substantially parallel to the bottom wall of the trench and vertical portions extending substantially perpendicular to the lateral portion and substantially parallel to the sidewalls of the trench.

Embodiments relate to a method for fabricating a semiconductor device that can include at least one of the following steps: forming a trench in a wafer; and then sequentially forming a first oxide film and a nitride film on sidewalls and a bottom wall of the trench; and then forming a second oxide film on the nitride film; and then planarizing the second oxide film; and then forming a polysilicon layer on the planarized second oxide film; and then forming an SONOS structure in the trench by patterning the polysilicon layer, the first oxide film, the nitride film and the second oxide film using the same etching mask. In accordance with embodiments, the nitride film includes a lateral portion extending substantially parallel to a bottom wall of the trench and vertical portions extending substantially perpendicular to the lateral portion and substantially parallel to the sidewalls of the trench.

Embodiments relate to a method for fabricating a semiconductor device that can include at least one of the following steps: forming a trench at a depth of 100 Å in an active region of a wafer; and then sequentially forming a tunnel oxide layer at a thickness of 20 Å, a charging trap layer at a thickness of 60 Å and a charge barrier layer at a thickness of 3000 Å in the trench; and then; and then planarizing the charge barrier layer; and then forming a polysilicon layer on the planarized charge barrier layer; and then forming an etching mask pattern on the polysilicon layer; and then forming a gate stack pattern in the trench by etching portions of the tunnel oxide layer, the charging trap layer, the charge barrier layer and the gate poly layer that are not formed in the trench using the etching mask pattern as a mask. In accordance with embodiments, the charging trap layer includes a lateral portion extending substantially parallel to a bottom wall of the trench and vertical portions extending substantially perpendicular to the lateral portion and substantially parallel to sidewalls of the trench.

### DRAWINGS

Example FIG. 1 illustrates a semiconductor device having a SONOS structure.

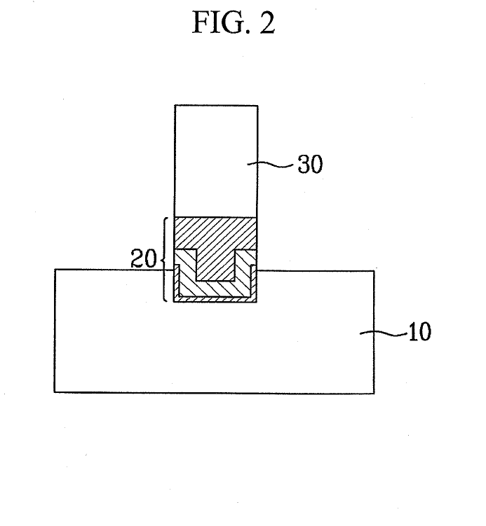

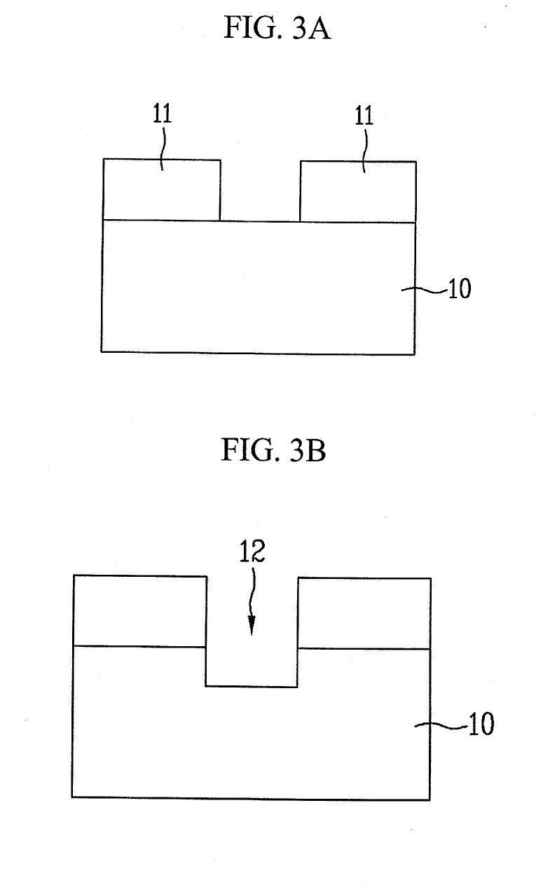

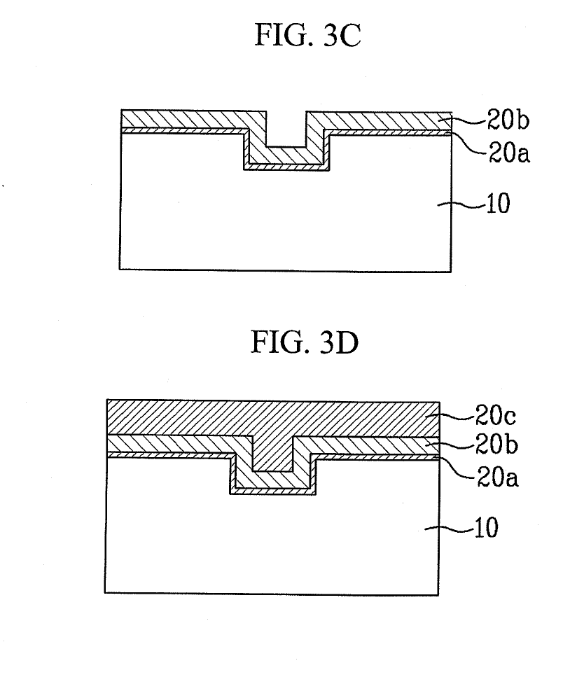

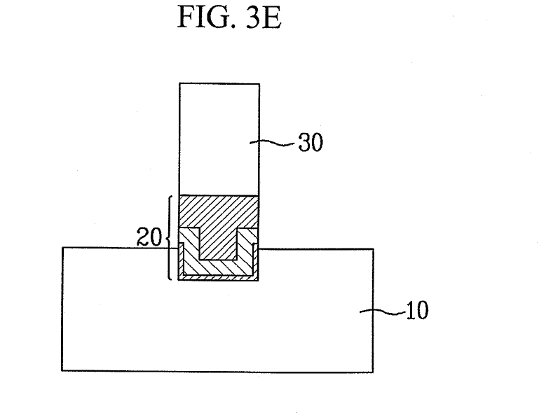

Example FIGS. 2 to 3 illustrate a semiconductor device having a SONOS structure, in accordance with embodiments.

### DESCRIPTION

A semiconductor device in accordance with embodiments can have a SONOS structure. Therefore, the semiconductor device in accordance with embodiments may have a structure that includes ONO films being stacked dielectric layers formed on and/or over an uppermost surface of an active region of a semiconductor substrate and a gate electrode formed on and/or over the uppermost surface of the ONO films. A source/drain junction can be formed in the semiconductor substrate. In particular, the semiconductor device in accordance with embodiments can effectively increase tunneling speed and a tunneled amount of charges in a process of performing programming and erasing by not employing a plane SONOS structure. In essence, the ONO films in a rugged structure are formed in the SONOS device to use a structure of expanding a surface area of a nitride layer serving as a charging trap layer. A recess gate structure is used to form the ONO films in the rugged structure.

As illustrated in example FIGS. 2 and 3, a semiconductor device having a SONOS structure can include ONO film 20 formed by sequentially stacking a tunnel oxide layer, a charging trap layer and a charge barrier layer on and/or over the uppermost surface of the active region of semiconductor substrate 10 such as a bare silicon (Bare Si) substrate. Gate electrode 30 can be formed on and/or over the uppermost surface of ONO film 20 and can be a gate electrode formed with conductive polysilicon. ONO film 20 can include first oxide film 20a corresponding to a tunnel oxide layer, nitride film 20b corresponding to a charging trap layer and second oxide film 20c corresponding to a charge barrier layer. Gate 30 can be a recessed gate, and thus, the semiconductor device having a SONOS structure in accordance with embodiments can be configured of recessed gate 30 and ONO film 20 formed in the rugged structure. ONO film 20 having the rugged structure can be formed on and/or over semiconductor substrate or silicon wafer 10. Wafer 10 has trench 12 formed in its active region formed with gate 30. ONO film 20 is formed in a rugged form in trench 12. In accordance with embodiments, the active region of silicon wafer 10 can be removed to a predetermined depth by an etching process using a photo resist pattern to thereby form trench 12 into which gate 30 is formed. Trench 12 can be formed in wafer 10 at a depth of about 100 Å by performing a dry etching process on wafer 10.

First oxide film 20a can then be formed on and/or over wafer 10 and in trench 12 at a thickness of 20 Å by wet oxidation. The portion of first oxide film 20a not formed in trench 12 can then be removed using an etching mask. Nitride film 20b can then be formed on and/or over the uppermost surface of first oxide film 20a and in trench 12 at a thickness of 60 Å and a portion of nitride film 20b not formed in trench 12 can then be removed using an etching mask, preferably, the same mask used to form first oxide film 20a. First oxide film 20a and nitride film 20b can be formed such that a sum of their thickness is smaller than the depth of trench 12. Second oxide film 20c can then be formed on and/or over an uppermost surface of nitride film 20b at a thickness of 3000 Å by hot temperature oxide. Second oxide film 20c can be formed having a concave shape. Second oxide film 20c can then be planarized by chemical mechanical polishing (CMP). After the CMP, the portion of second oxide film 2c not formed in the trench region can be removed using the same etching mask used in forming first oxide film 20a and nitride film 20b. Gate 30 can then be formed on and/or over the uppermost surface of planarized second oxide film 20c at a thickness of 2100 Å using the same etching mask used for forming ONO film 20.

Example FIGS. 3A to 3E illustrate a process for manufacturing a semiconductor device having a SONOS structure in accordance with embodiments. As illustrated in example FIG. 3A, photo resist patterns 11 for forming trench 12 in silicon wafer 10 is formed on and/or over wafer 10. Preferably, the photo resist is formed at a thickness of 1000 Å.

As illustrated in example FIG. 3B, the active region of silicon wafer 10 can then be removed to a predetermined depth by performing an etching process using photo resist patterns 11. The depth of trench is preferably about 100 Å and at least one of a dry etching and reactive ion etching (RIE) can preferably be used for forming trench 12. After trench 12 is formed, photo resist patterns 11 can be removed.

As illustrated in example FIG. 3C, first oxide film 20a serving as a tunnel oxide layer is formed on and/or over silicon wafer 10 and in trench 12. Nitride film 20b serving as a charging trap layer can then be formed on and/or over first oxide film 20a. Preferably, first oxide film 20a is formed using wet oxidation at a thickness of 20 Å while nitride film 20b is formed at a thickness of 60 Å.

As illustrated in example FIG. 3D, second oxide film 20c serving as a charge barrier layer can then be formed on and/or over nitride film 20b. Preferably, second oxide film 20c is formed using a hot temperature oxide at a thickness of 3000 Å. After the deposition of second oxide film 20c, second oxide film 20c is then planarized. Preferably, the planarization process is performed using chemical mechanical polishing (CMP). After ONO film 20 is formed by the foregoing process, a gate poly can then be formed on and/or over the uppermost surface of second oxide film 20c at a thickness of 2100 Å.

As illustrated in example FIG. 3E, the etching mask pattern is formed for removing the stack portion outside of trench 12 region and an SONOS gate stack is formed using the formed etching mask pattern.

In accordance with embodiments, the sum of the deposited thickness of first oxide film 20a and nitride film 20b can be smaller than the depth of trench 12, thereby making it possible to form the rugged structure in trench 12, i.e, in a substantially U-shaped pattern on and/or over sidewalls and the bottom surface of trench 12. Thereby, the total surface area of nitride film 20b serving as the charging trap layer is increased.

In accordance with embodiments, the total surface area of the charging trap layer can be increased by forming a trench in a silicon wafer and forming the charging trap layer on and/or over sidewalls and on and/or over the bottom surface of the trench, thereby making it possible to provide a trap site capable of trapping a large amount of charges. Increasing the overall surface area of the charging trap layer makes it possible to increase the amount of electrons FN-tunneled without making the thickness of the ONO film considerably thin. Moreover, the tunneling speed can be increased in the process of performing programming and erasing functions by not utilizing a plane SONOS structure, thereby making it possible to secure the reliability of the SONOS device for preserving data.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a wafer having a trench formed in an active region thereof;
a first oxide film, a nitride film, and a second oxide film sequentially formed on the trench, wherein the nitride film includes a lateral portion extending substantially parallel to a bottom wall of the trench and vertical portions extending substantially perpendicular to the lateral portion and substantially parallel to sidewalls of the trench.

2. The semiconductor device of claim 1, wherein the trench is formed at a predetermined depth of depth of 100 Å.

3. The semiconductor device of claim 2, wherein the total thickness of the first oxide film and the nitride film is less than the predetermined depth of the trench.

4. The semiconductor device of claim 1, wherein the first oxide film is formed at a thickness of 20 Å.

5. The semiconductor device of claim 4, wherein the nitride film is formed at a thickness of 60 Å.

6. The semiconductor device of claim 5, wherein the total sum of the respective thickness of the first oxide film and the nitride film is less than a depth of the trench.

7. The semiconductor device of claim 1, wherein the second oxide film is formed at a thickness of 3000 Å.

8. The semiconductor device of claim 1, wherein the trench is formed at a depth of 100 Å, the first oxide film is formed at a thickness of 20 Å and the nitride film is formed at a thickness of 60 Å.

9. The semiconductor device of claim 1, further comprising a gate formed on the uppermost surface of the second oxide film.

10. A method for fabricating a semiconductor device comprising:
forming a trench in a wafer; and then
sequentially forming a first oxide film and a nitride film on sidewalls and a bottom wall of the trench; and then
forming a second oxide film on the nitride film; and then
planarizing the second oxide film; and then
forming a polysilicon layer on the planarized second oxide film; and then
forming an SONOS structure in the trench by patterning the polysilicon layer, the first oxide film, the nitride film and the second oxide film using the same etching mask,
wherein the nitride film includes a lateral portion extending substantially parallel to a bottom wall of the trench and vertical portions extending substantially perpendicular to the lateral portion and substantially parallel to the sidewalls of the trench.

11. The method of claim 10, wherein forming the trench comprises:
forming photo resist patterns on the wafer; and then
etching the wafer to a predetermined depth using the photo resist patterns as etch masks; and then
removing the photo resist patterns.

12. The method of claim 11, wherein the wafer is etched to the predetermined depth using a dry etching process.

13. The method according to claim 10, wherein the first oxide film is formed using a wet oxidation process.

14. The method of claim 10, wherein the second oxide film is formed using a high oxidation process.

15. The method of claim 10, wherein the second oxide film is planarized using a chemical mechanical polishing process.

16. A method for fabricating a semiconductor device comprising:
forming a trench at a depth of 100 Å in an active region of a wafer; and then sequentially forming a tunnel oxide layer at a thickness of 20 Å, a charging trap layer at a thickness of 60 Å and a charge barrier layer at a thickness of 3000 Å in the trench; and then
planarizing the charge barrier layer; and then
forming a trench at a depth of 100 Å in an active region of a wafer; and then
sequentially forming a tunnel oxide layer at a thickness of 20 Å, a charging trap layer at a thickness of 60 Å and a charge barrier layer at a thickness of 3000 Å in the trench; and then
planarizing the charge barrier layer; and then
forming a polysilicon layer on the planarized charge barrier layer; and then
forming an etching mask pattern on the polysilicon layer; and then
forming a gate stack pattern in the trench by etching portions of the tunnel oxide layer, the charging trap layer, the charge barrier layer and the gate poly layer that are not formed in the trench using the etching mask pattern as a mask,
wherein the charging trap layer includes a lateral portion extending substantially parallel to a bottom wall of the trench and vertical portions extending substantially perpendicular to the lateral portion and substantially parallel to sidewalls of the trench.

17. The method of claim 16, wherein forming the trench comprises:
forming photo resist patterns on the wafer; and then
etching the wafer by at least one of dry etching and reactive ion etching using the photoresist patterns as masks; and then
removing the photo resist patterns.

18. The method of claim 16, wherein the tunnel oxide layer comprises a first oxide layer, the charging trap layer comprises a nitride layer and the charge barrier layer comprises a second oxide layer.

19. The method of claim 16, wherein sequentially forming the tunnel oxide layer, the charging trap layer and the charge barrier layer comprises:
forming a first oxide layer as the tunnel oxide layer partially in the trench; and then
forming a nitride layer as the charging trap layer partially in the trench and on the first oxide layer; and then
forming a second oxide layer as the charge barrier layer partially in the trench and on the nitride layer.

20. The method of claim 16, wherein the gate stack pattern comprises an SONOS structure.
